(19) United States
(12) Patent Application Publication
(10) Pub. No.: US 2022/0416755 A1
(43) Pub. Date: Dec. 29, 2022

(54) ACOUSTIC IMPEDANCE MATCHING MATERIAL AND SYSTEM

(71) Applicants: Dinesh Kommireddy, Houston, TX (US); Navin Sakthivel, Spring, TX (US); Aaron Avagliano, Tomball, TX (US)

(72) Inventors: Dinesh Kommireddy, Houston, TX (US); Navin Sakthivel, Spring, TX (US); Aaron Avagliano, Tomball, TX (US)

(73) Assignee: Baker Hughes Oilfield Operations LLC, Houston, TX (US)

(21) Appl. No.: 17/361,622

(22) Filed: Jun. 29, 2021

(51) Int. Cl. H03H 9/00; G01N 29/28; G01N 29/02; E21B 41/00

(52) U.S. Cl. CPC H03H 9/0004; G01N 29/28; G01N 29/02; E21B 41/0071

(57) ABSTRACT

An acoustic matching material for gas measurement including a matrix material having an acoustic impedance and an acoustic impedance reduction material, having an acoustic impedance lower than the acoustic impedance of the matrix material, the acoustic impedance reduction material being dispersed in the matrix material to create an acoustic impedance graduation through a thickness of the matching material.

### BACKGROUND

In the resource recovery industry, it is commonly necessary to monitor flare gas. This is generally done with a piezoelectric crystal. Known to the art is that the acoustic impedance of flare gas and that of the crystal is significantly different and therefore an impedance matching material is generally placed between the flare gas and the crystal. Such materials are usually epoxy based. While such materials do help with measurement, they also suffer from signal losses that are still ideally unacceptable. The art would welcome improved acoustic impedance matching materials.

### SUMMARY

An embodiment of an acoustic matching material for gas measurement including a matrix material having an acoustic impedance and an acoustic impedance reduction material, having an acoustic impedance lower than the acoustic impedance of the matrix material, the acoustic impedance reduction material being dispersed in the matrix material to create an acoustic impedance graduation through a thickness of the matching material.

### BRIEF DESCRIPTION OF THE DRAWINGS

The following descriptions should not be considered limiting in any way. With reference to the accompanying drawings, like elements are numbered alike:

FIG. 1 is a schematic view of a flare gas measurement configuration having an acoustic impedance matching material as disclosed herein; and

FIG. 2 is a view of a hydrocarbon processing system including the material disclosed herein.

### DETAILED DESCRIPTION

A detailed description of one or more embodiments of the disclosed apparatus and method are presented herein by way of exemplification and not limitation with reference to the Figures.

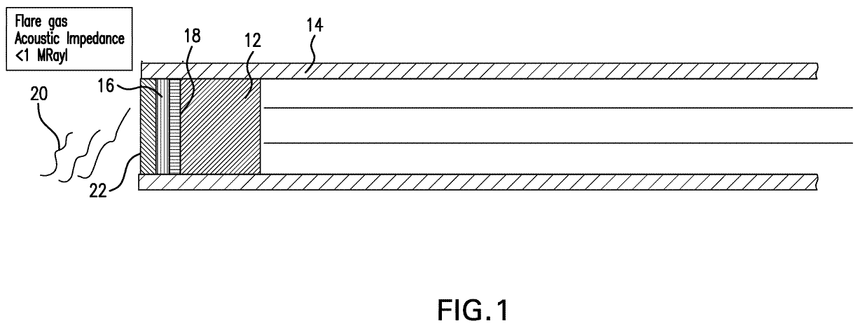

Referring to FIG. 1, a schematic view of a measurement configuration 10 is illustrated. In an embodiment, the measurement configuration may make measurements related to a gas. In a particular example, the gas may be a flare gas. The configuration 10 includes a piezo crystal 12 disposed in a housing 14. Adjacent the piezo crystal 12 is an acoustic impedance matching material 16 that is in contact with the crystal 12 on one side 18 and in contact with a gas 20 on the other side 22. Acoustic impedance is defined according to the relationship: Acoustic impedance=Speed of Sound multiplied by Material Density. The general configuration just described is known but the matching material 16 described herein is new and superior to prior art efforts. In order to improve measurement operations for gas 20, it is necessary to recognize that, for example, flare gas typically has an acoustic impedance of less than 1 MRayl whereas the crystal 12 typically has an acoustic impedance of greater than 18 MRayl. This differential is excessive for reliable measuring operations due to signal scattering and consequent degradation. To improve performance, then, the acoustic impedance mismatch must be bridged by the material 16. As noted above, the prior art has attempted to bridge acoustic impedances with epoxy materials but has been only partially successful. Using a geometric mean for the acoustic impedance as the target for the matching material of the prior art still leaves steps in differential impedance that are too large for optimum signal propagation. The steps result in signal scattering and reduced measurement reliability. With the matching material of this disclosure, however, a geometric mean of acoustic impedance is created at every cross section that one can take of the matching material 16. The number of cross sections is infinite and there will be infinite geometric means, one for every cross section. This results in a graduation of acoustic impedance over a thickness of the material 16. The graduations are much smaller steps in acoustic impedance and hence create less scatter in the signal. In embodiments, the graduation is so incremental that a continuum of acoustic impedance is created meaning that there is more of a ramp of acoustic impedance rather than steps of acoustic impedance. The continuum provides even greater reduction in scattering loss for the signal and accordingly better conduction of the full signal on its path between the gas and the crystal 12. Better conduction of the signal equates to better measurement of the gas.

Matching material 16 comprises a matrix material that may be, for example, a thermoplastic. Specific examples of thermoplastic contemplated include but are not limited to nylon or polystyrene. To the matrix is added an acoustic impedance reduction material, having an acoustic impedance lower than the acoustic impedance of the matrix material, which is of course a function of density in accordance with the mathematical expression recited above. For example, one matrix material may have a density of 1.1 g/cc while the acoustic impedance reduction material may have a density of 0.01 g/cc. Acoustic impedance reduction material, in an embodiment, may comprise polystyrene microspheres or material having similar properties such as silica or glass based aerogels or microspheres. In embodiments, the acoustic impedance reduction material may comprise from about 10% to about 80% of the matching material by volume. Additionally, to be noted is that the particular materials recited provide for excellent thermal stability at temperatures normally experienced by flare gas measuring apparatus.

The acoustic reduction material is dispersed in the matrix material in a graduated condition such that the number of particles of the reduction material will gradually increase from one side 18 of the material to the other side 22 of the material. This will cause the acoustic impedance of the material 16 to change through its thickness as described above, a functionally graded material. Distribution of the reduction material is achieved by a spreader, nozzle, hopper, etc. while adjusting the flow rate to cause a change in the percentage of reduction material to matrix material with distance from one side 18 or the other 22.

With the matrix material and the reduction material disposed as appropriate (meaning with the desired graduation of reduction material and in a shape needed for the application), the graduated acoustic impedance matching material is subjected to heat from about 150 C to about 250 C and an SLS (Selective Laser Sintering) process, an additive manufacturing process, to fuse the matrix and reduction materials together permanently.

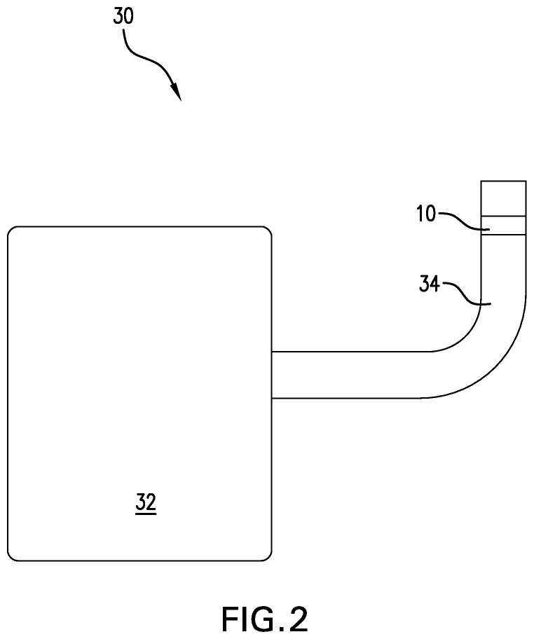

Referring to FIG. 2, a hydrocarbon processing system 30 is illustrated schematically. The system includes a structure 32 that processes hydrocarbons and includes a conduit 34 for a gas, which may in some cases be a flare gas. A gas measurement configuration 10 is disposed in operable contact with the conduit 34.

Set forth below are some embodiments of the foregoing disclosure:

Embodiment 1: An acoustic matching material for gas measurement including a matrix material having an acoustic impedance and an acoustic impedance reduction material, having an acoustic impedance lower than the acoustic impedance of the matrix material, the acoustic impedance reduction material being dispersed in the matrix material to create an acoustic impedance graduation through a thickness of the matching material.

Embodiment 2: The acoustic matching material as in any prior embodiment, wherein the matrix material is a thermoplastic material.

Embodiment 3: The acoustic matching material as in any prior embodiment, wherein the matrix material is nylon.

Embodiment 4: The acoustic matching material as in any prior embodiment, wherein the matrix material is polystyrene.

Embodiment 5: The acoustic matching material as in any prior embodiment, wherein the acoustic impedance reduction material is microspheric material.

Embodiment 6: The acoustic matching material as in any prior embodiment, wherein the microspheric material is polystyrene.

Embodiment 7: The acoustic matching material as in any prior embodiment, wherein the graduation is from one surface of the matching material to an opposite surface of the matching material.

Embodiment 8: The acoustic matching material as in any prior embodiment, wherein the graduation provides a different geometric mean acoustic impedance at every cross section of the matching material.

Embodiment 9: The acoustic matching material as in any prior embodiment, wherein the graduation is a continuum.

Embodiment 10: A method for measuring a gas including propagating a signal between a crystal and a flare gas through an acoustic matching material as in any prior embodiment.

Embodiment 11: The method as in any prior embodiment, wherein the gas is a flare gas.

Embodiment 12: A gas measurement device including a housing, a piezo-crystal disposed in the housing, and an acoustic matching material as in any prior embodiment disposed adjacent the piezo-crystal.

Embodiment 13: The device as in any prior embodiment, wherein the gas is a flare gas

Embodiment 14: A hydrocarbon processing system including a structure through which a gas is propagated. a gas measurement device as in any prior embodiment disposed in operable contact with the structure.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” can include a range of ±8% or 5%, or 2% of a given value.

The teachings of the present disclosure may be used in a variety of well operations. These operations may involve using one or more treatment agents to treat a formation, the fluids resident in a formation, a wellbore, and/or equipment in the wellbore, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. An acoustic matching material for gas measurement comprising:
a matrix material having an acoustic impedance; and
an acoustic impedance reduction material, having an acoustic impedance lower than the acoustic impedance of the matrix material, the acoustic impedance reduction material being dispersed in the matrix material to create an acoustic impedance graduation through a thickness of the matching material.

2. The acoustic matching material as claimed in claim 1 wherein the matrix material is a thermoplastic material.

3. The acoustic matching material as claimed in claim 2 wherein the matrix material is nylon.

4. The acoustic matching material as claimed in claim 2 wherein the matrix material is polystyrene.

5. The acoustic matching material as claimed in claim 1 wherein the acoustic impedance reduction material is microspheric material.

6. The acoustic matching material as claimed in claim 5 wherein the microspheric material is polystyrene.

7. The acoustic matching material as claimed in claim 1 wherein the graduation is from one surface of the matching material to an opposite surface of the matching material.

8. The acoustic matching material as claimed in claim 7 wherein the graduation provides a different geometric mean acoustic impedance at every cross section of the matching material.

9. The acoustic matching material as claimed in claim 1 wherein the graduation is a continuum.

10. A method for measuring a gas comprising:
propagating a signal between a crystal and a flare gas through an acoustic matching material as claimed in claim 1.

11. The method as claimed in claim 10 wherein the gas is a flare gas.

12. A gas measurement device comprising:
a housing;
a piezo-crystal disposed in the housing; and
an acoustic matching material as claimed in claim 1 disposed adjacent the piezo-crystal.

13. The device as claimed in claim 12 wherein the gas is a flare gas

14. A hydrocarbon processing system comprising:
a structure through which a gas is propagated;
a gas measurement device as claimed in claim 12 disposed in operable contact with the structure.
